(19) United States
(12) Patent Application Publication
(10) Pub. No.: US 2024/0094150 A1
(43) Pub. Date: Mar. 21, 2024

(54) NON-DESTRUCTIVE SEM-BASED DEPTH-PROFILING OF SAMPLES

(71) Applicant: APPLIED MATERIALS ISRAEL LTD., Rehovot (IL)

(72) Inventors: Dror Shemesh, Hod Hasharon (IL); Doron Girmonsky, Raanana (IL); Uri Hadar, Tel-Aviv (IL); Michal Eilon, Beit-Elazari (IL)

(73) Assignee: APPLIED MATERIALS ISRAEL LTD., Rehovot (IL)

(21) Appl. No.: 17/947,481

(22) Filed: Sep. 19, 2022

(51) Int. Cl. G01N 23/2251; H01J 37/29

(52) U.S. Cl. CPC G01N 23/2251; H01J 37/292; G01N 2223/053; G01N 2223/305; G01N 2223/306; H01J 2237/22; H01J 2237/2815

(57) ABSTRACT

Disclosed herein is a computer-based method for non-destructive depth-profiling of samples. The method includes a measurement operation and a data analysis operation. The measurement operation includes, for each of a plurality of landing energies: (i) projecting an electron beam on a sample, which penetrates the sample to a respective depth determined by the landing energy, and (ii) sensing electrons returned from the sample, thereby obtaining a respective sensed electrons data set. The data analysis operation includes generating from the sensed electrons data sets a concentration map, which characterizing at least a vertical dimension of the sample.

### TECHNICAL FIELD

The present disclosure relates generally to non-destructive scanning electron microscopy-based depth-profiling of samples.

### BACKGROUND OF THE INVENTION

“Three-dimensional” structures are increasingly used in the semiconductor industry, particularly, in the manufacture of logic and memory components. Accordingly, the ability to obtain structural data of a sample, and to analyze the obtained data to extract a three-dimensional characterization of the sample, has become crucial. At present, most depth-profiling techniques are destructive, typically involving transmission electron microscopy (TEM) and/or the extraction of lamellas, or shaving off of slices, from the sample and subsequent analysis thereof. The challenge remains to develop non-destructive depth-profiling techniques, which will allow for high-volume manufacturing (HVM).

### BRIEF SUMMARY OF THE INVENTION

Aspects of the disclosure, according to some embodiments thereof, relate to non-destructive scanning electron microscopy based depth-profiling of samples. More specifically, but not exclusively, aspects of the disclosure, according to some embodiments thereof, relate to non-destructive depth-profiling of semiconductor structures based on sensing of (at least) backscattered electrons. Even more specifically, but not exclusively, aspects of the disclosure, according to some embodiments thereof, relate to validation of the concentrations of one or more substances in memory and logic components, such as gate stacks, based on sensing of (at least) backscattered electrons.

Thus, according to an aspect of some embodiments, there is provided a computer-based method for non-destructive depth-profiling of samples. The method includes:
A measurement operation including for each of a plurality of landing energies, selected so as to allow probing the sample to a plurality of depths:
   Projecting an electron beam (e-beam) on a sample. The e-beam penetrates the sample to a respective depth determined by the landing energy.
   ▪Sensing electrons returned from the sample to obtain a sensed electron data set.
A data analysis operation in which a concentration map is generated based (at least) on the sensed electrons data sets (pertaining to each of the e-beams. The concentration map characterizes at least a vertical dimension of the sample.

According to some embodiments of the method, the measurement operation is performed with respect to each of a plurality of lateral locations on the sample on which the respective plurality of e-beams is projected. In the data analysis operation, the sensed electrons data sets, obtained by projecting the e-beams on each of the lateral locations, are taken into account in generating the concentration map, which is three-dimensional.

According to some embodiments of the method, the sensing of the electrons, includes, for each of a plurality of return angles, measuring a respective intensity of electrons returned at the return angle.

According to some embodiments of the method, the sensing of the electrons includes, for each of a plurality of pixels on an electron image sensor, measuring a respective intensity of electrons returned thereto (i.e. incident on the pixel).

According to some embodiments of the method, the sensed electrons include backscattered electrons. According to some such embodiments, the sensed electrons further include secondary electrons.

According to some embodiments of the method, for each landing energy, elastic interactions between electrons from the e-beam and the sample, leading to reflection of electrons from the e-beam, are substantially limited to a respective volume within the sample, which is substantially centered about a depth that increases with the landing energy and whose size increases with the landing energy.

According to some embodiments of the method, in the data analysis operation, a design intent of the sample is taken into account.

According to some embodiments of the method, at each map coordinate(s) the concentration map specifies a substance, which has a highest density about the map coordinate(s) out of a plurality of substances, which the sample includes.

According to some embodiments of the method, at each map coordinate(s) the concentration map specifies densities of one or more substances, which are included in the sample.

According to some embodiments of the method, each of the one or more densities is specified to within one of (i.e. one density range out) a plurality of density ranges.

According to some embodiments of the method, the density is a mass density, a particle density (e.g. atomic density), or a function of the mass density and the particle density.

According to some embodiments of the method, the sample is a semiconductor specimen.

According to some embodiments of the method, the sample is a patterned wafer.

According to some embodiments of the method, the sample includes a semiconductor structure.

According to some embodiments of the method, in the data analysis operation, the concentration map is obtained as an output of a machine learning (ML) derived algorithm, whose inputs include the sensed electrons data sets, obtained for each of the landing energies and labelled thereby.

According to some embodiments of the method, the concentration map is three-dimensional. The sensed electrons data sets corresponding to each e-beam are further labelled by lateral coordinates of the lateral location at which the e-beam was projected.

According to some embodiments of the method, the ML derived algorithm is a neural network (NN).

According to some embodiments of the method, wherein at each map coordinate(s) the concentration map specifies a substance, which has a highest density about the map coordinate(s), out of a plurality of substances, which the sample includes, the NN is a classification NN.

According to some embodiments of the method, wherein at each map coordinate(s) the concentration map specifies densities of the one or more substances, which the sample includes, to within one of the plurality of density ranges, the NN is a classification NN.

According to some embodiments of the method, the classification NN is a convolutional NN, an AlexNet, a residual NN (ResNet), or a VGG NN, or includes a VAE.

According to some embodiments of the method, the NN selected from a convolutional NN and a fully connected NN.

According to some embodiments of the method, the NN is a regression NN.

According to some embodiments of the method, the measurement operation includes sensing electrons returned each of two or more return angles, respectively.

According to an aspect of some embodiments, there is provided a system for non-destructive depth-profiling of samples. The system includes:
An electron beam (e-beam) source configured to project e-beams on a sample at each of a plurality of landing energies, so as to allow (i.e. enable) probing the sample to a plurality of depths.
An electron sensing module configured to sense electrons returned from the sample, and thereby obtained a respective electron data set.
A computational module configured to generate a concentration map of the sample based (at least) on sensed electrons data sets obtained by the electron sensing module for each of the plurality of landing energies. The concentration map characterizes at least a vertical dimension of the sample.

According to some embodiments of the system, the system is further configured to allow projecting the e-beams on each of controllably selectable lateral locations on the sample. The computational module is configured to, in generating the concentration map, take into account sensed electrons data sets, obtained by the electron sensing module for each of the lateral locations. The concentration map is three-dimensional.

According to some embodiments of the system, the sensed electrons include backscattered electrons. According to some such embodiments, the sensed electrons further include secondary electrons.

According to some embodiments of the system, the electron sensing module includes two or more electron sensors configured to sense electrons returned at each of two or more return angles, respectively.

According to some embodiments of the system, the electron sensing module includes one or more backscattered electron (BSE) detectors.

According to some embodiments of the system, the computational module is configured to, in generating the concentration map, take into account a design intent of the sample.

According to some embodiments of the system, at each map coordinate(s) the concentration map specifies a substance, which has a highest density about the map coordinate(s) out of a plurality of substances included in the sample.

According to some embodiments of the system, at each map coordinate(s) the concentration map specifies densities of one or more substances included in the sample.

According to some embodiments of the system, each of the densities is specified to within a respective one of a plurality, or a respective plurality (i.e. in embodiments wherein different substances may be specified to different resolutions), of density ranges.

According to some embodiments of the system, the density is a mass density, a particle density (e.g. an atomic density), or a function of the mass density and the particle density.

According to some embodiments of the system, the sample is a semiconductor specimen.

According to some embodiments of the system, the sample is a patterned wafer.

According to some embodiments of the system, the sample includes a semiconductor structure.

According to some embodiments of the system, the computational module is configured to execute a machine learning (ML) derived algorithm. The inputs of the ML derived algorithm include the sensed electrons data sets, each labelled at least by the respective landing energy. The output of the ML derived algorithm is the concentration map.

According to some embodiments of the system, wherein the concentration map is three-dimensional, the sensed electrons data sets are further labelled by lateral coordinates of the lateral location at which the respective e-beam was projected.

According to some embodiments of the system, the ML derived algorithm is a neural network (NN).

According to some embodiments of the system, wherein at each map coordinate(s) the concentration map specifies a substance, having a highest density about the map coordinate(s), out of a plurality of substances included in the sample, the NN is a classification NN.

According to some embodiments of the system, wherein at each map coordinate(s) the concentration map specifies, to within a respective one of the plurality, or the respective plurality, of density ranges, densities of the one or more substances included in the sample, the NN is a classification NN.

According to some embodiments of the system, the classification NN is a convolutional NN, an AlexNet, a residual NN (ResNet), a VGG NN, or includes a VAE.

According to some embodiments of the system, the NN selected from a convolutional NN and a fully connected NN.

According to some embodiments of the system, the NN is a regression NN.

According to an aspect of some embodiments, there is provided a method for training a neural network (NN) for non-destructive depth-profiling of samples. The method includes operations of:
Generating training data for a NN, which is configured to receive as inputs, sensed electrons data sets of a sample, obtained for each of a plurality of landing energies of inducing electron beams (e-beams), and to output a concentration map of the sample, by suboperations of:
   Generating calibration data by, for each of a plurality of samples:
      Projecting on the sample a plurality of e-beams at a first plurality of landing energies, respectively, and sensing electrons returned from the sample.
      Obtaining a measured concentration map, which characterizes at least a vertical dimension of the sample.
   Generating simulated training data for the NN by:
      Using the calibration data (i.e. the measured concentration maps and the sensed electrons data sets) to calibrate a computer simulation, which is configured to receive as inputs a concentration map of a sample, and a landing energy of an e-beam projected on the sample, and output a corresponding simulated electrons data set.
      Using the calibrated computer simulation to generate simulated electrons data sets corresponding to additional landing energies and/or additional samples.
Training the NN using (i) at least the simulated electrons data sets, each labelled by the respective landing energy, as inputs, and (ii) concentration maps, corresponding to the simulated electrons data sets, respectively, as outputs.

According to some embodiments of the method, the computer simulation is calibrated such that for each pair of (i) measured concentration map, obtained in the suboperation of generating the calibration data, and (ii) landing energy, which is input into the computer simulation, a simulated electrons data set, output by the computer simulation, agree to within a required precision with the respective sensed electrons data set (obtained in the suboperation of projecting the plurality of e-beams on the sample).

According to some embodiments of the method, the sensed electrons include backscattered electrons. According to some such embodiments, the sensed electrons further include secondary electrons.

According to some embodiments of the method, the sensed electrons data sets, used as inputs for the NN, are obtained for each of a plurality of lateral locations on which the inducing e-beams respectively impinge on the sample. Each of the sensed electrons data sets is additionally labelled by the lateral location on which the respective inducing e-beam impinged. In the generating of the calibration data, the pluralities of e-beams are projected at pluralities of lateral locations on the samples, respectively. The measured concentration maps are three-dimensional.

According to some embodiments of the method, prior to the calibration suboperation, the computer simulation specifies initial point spread functions (PSFs) at least for each of the first plurality of landing energies. In the calibration suboperation, the initial PSFs are calibrated, thereby obtaining calibrated PSFs.

According to some embodiments of the method, the calibrated PSFs are obtained by about maximizing a likelihood for obtaining the sensed electrons data sets, given the measured concentration maps and starting from the initial PSFs. According to some such embodiments, as part of the maximization, regularization is used.

According to some embodiments of the method, a modified Richardson-Lucy algorithm is used to obtain the calibrated PSFs.

According to some embodiments of the method, an adjustable U-Net deep learning NN is used to obtain the calibrated PSFs from the initial PSFs. Parameters of the U-Net deep learning NN is optimized over under a constraint that the sensed electrons data sets are obtained from the measured concentration maps, respectively, when the respective calibrated PSFs, obtained from the initial PSFs using the U-Net deep learning NN, are used.

According to some embodiments of the method, the additional samples are of different design intent than the plurality of samples.

According to some embodiments of the method, the method may further include reapplying (i.e. reperforming) the operation of generating the simulated training data sets and the operation of training the NN when additional calibration data is available.

According to some embodiments of the method, a ratio of a number of the simulated electrons data sets to a number of the sensed electrons data sets may be between about 100 and about 1,000.

According to some embodiments of the method, the measured concentration maps are obtained by profiling lamellas extracted from each of the plurality samples and/or slices shaved thereof.

According to some embodiments of the method, the profiling of lamellas is performed using transmission electron microscopy and/or a scanning electron microscopy.

According to some embodiments of the method, each of the plurality of samples is a semiconductor specimen.

According to some embodiments of the method, each of the plurality of samples is a patterned wafer.

According to some embodiments of the method, each of the plurality of samples includes a semiconductor structure.

According to some embodiments of the method, the NN is a classification NN. The concentration map (output by the NN) specifies at each map coordinate(s) a substance, which, out of a plurality of substances included in the sample, has a highest density about the map coordinate(s).

According to some embodiments of the method, the NN is a classification NN. The concentration map (output by the NN) specifies to within one of a plurality of density ranges at each map coordinate(s) a density of at least substance, which the sample includes.

According to some embodiments of the method, the classification NN is a convolutional NN, an AlexNet, a residual NN (ResNet), or a VGG NN, or includes a VAE.

According to some embodiments of the method, the density is a mass density, a particle density (e.g. atomic density), or a function of the mass density and the particle density.

According to some embodiments of the method, the NN is a regression NN selected from a convolutional NN and a fully connected NN.

According to some embodiments of the method, in the suboperation of generating the calibration data, the sensing of electrons includes sensing electrons returned at two or more scattering angles.

According to an aspect of some embodiments, there is provided a non-transitory computer-readable storage medium storing instructions that cause a system for non-destructive depth-profiling of samples (such as the above-described system) to implement the above-described method for non-destructive depth-profiling of samples.

Certain embodiments of the present disclosure may include some, all, or none of the above advantages. One or more other technical advantages may be readily apparent to those skilled in the art from the figures, descriptions, and claims included herein. Moreover, while specific advantages have been enumerated above, various embodiments may include all, some, or none of the enumerated advantages.

Unless otherwise defined, all technical and scientific terms used herein have the same meaning as commonly understood by one of ordinary skill in the art to which this disclosure pertains. In case of conflict, the patent specification, including definitions, governs. As used herein, the indefinite articles “a” and “an” mean “at least one” or “one or more” unless the context clearly dictates otherwise.

Unless specifically stated otherwise, as apparent from the disclosure, it is appreciated that, according to some embodiments, terms such as “processing”, “computing”, “calculating”, “determining”, “estimating”, “assessing”, “gauging” or the like, may refer to the action and/or processes of a computer or computing system, or similar electronic computing device, that manipulate and/or transform data, represented as physical (e.g. electronic) quantities within the computing system's registers and/or memories, into other data similarly represented as physical quantities within the computing system's memories, registers or other such information storage, transmission or display devices.

Embodiments of the present disclosure may include apparatuses for performing the operations herein. The apparatuses may be specially constructed for the desired purposes or may include a general-purpose computer(s) selectively activated or reconfigured by a computer program stored in the computer. Such a computer program may be stored in a computer readable storage medium, such as, but not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), magnetic or optical cards, flash memories, solid state drives (SSDs), or any other type of media suitable for storing electronic instructions, and capable of being coupled to a computer system bus.

The processes and displays presented herein are not inherently related to any particular computer or other apparatus. Various general-purpose systems may be used with programs in accordance with the teachings herein, or it may prove convenient to construct a more specialized apparatus to perform the desired method(s). The desired structure(s) for a variety of these systems appear from the description below. In addition, embodiments of the present disclosure are not described with reference to any particular programming language. It will be appreciated that a variety of programming languages may be used to implement the teachings of the present disclosure as described herein.

Aspects of the disclosure may be described in the general context of computer-executable instructions, such as program modules, being executed by a computer. Generally, program modules include routines, programs, objects, components, data structures, and so forth, which perform particular tasks or implement particular abstract data types. Disclosed embodiments may also be practiced in distributed computing environments where tasks are performed by remote processing devices that are linked through a communications network. In a distributed computing environment, program modules may be located in both local and remote computer storage media including memory storage devices.

### BRIEF DESCRIPTION OF THE DRAWINGS

Some embodiments of the disclosure are described herein with reference to the accompanying figures. The description, together with the figures, makes apparent to a person having ordinary skill in the art how some embodiments may be practiced. The figures are for the purpose of illustrative description and no attempt is made to show structural details of an embodiment in more detail than is necessary for a fundamental understanding of the disclosure. For the sake of clarity, some objects depicted in the figures are not drawn to scale. Moreover, two different objects in the same figure may be drawn to different scales. In particular, the scale of some objects may be greatly exaggerated as compared to other objects in the same figure.

In the figures:

FIG. 1 presents a flowchart of a non-destructive scanning electron microscopy-based method for depth-profiling of samples, according to some embodiments;

FIG. 2A to 2D schematically depict a sample undergoing depth-profiling in accordance with the method of FIG. 1, according to some embodiments;

FIG. 3 presents a flowchart of a non-destructive scanning electron microscopy-based method for depth-profiling of samples, which corresponds to specific embodiments of the method of FIG. 1, wherein the depth-profiling is three-dimensional;

FIGS. 4A and 4B schematically depict a sample undergoing depth-profiling in accordance with the method of FIG. 3, according to some embodiments thereof;

FIG. 5 schematically depicts a sample undergoing depth-profiling in accordance with the method of FIG. 3, according to some embodiments thereof;

FIG. 6 schematically depicts a system for non-destructive scanning electron microscopy-based depth-profiling of samples, according to some embodiments;

FIG. 7 schematically depicts an electron irradiation and sensing assembly, which corresponds to specific embodiments of an electron irradiation and sensing assembly of the system of FIG. 6; and

FIG. 8 presents a method for training a neural network to derive from backscattered electrons data, obtained from a sample, a concentration map thereof, according to some embodiments.

### DETAILED DESCRIPTION OF THE INVENTION

The principles, uses, and implementations of the teachings herein may be better understood with reference to the accompanying description and figures. Upon perusal of the description and figures present herein, one skilled in the art will be able to implement the teachings herein without undue effort or experimentation. In the figures, same reference numerals refer to same parts throughout.

In the description and claims of the application, the words “include” and “have”, and forms thereof, are not limited to members in a list with which the words may be associated.

As used herein, the term “about” may be used to specify a value of a quantity or parameter (e.g. the length of an element) to within a continuous range of values in the neighborhood of (and including) a given (stated) value. According to some embodiments, “about” may specify the value of a parameter to be between 80% and 120% of the given value. For example, the statement “the length of the element is equal to about 1 m” is equivalent to the statement “the length of the element is between 0.8 m and 1.2 m”. According to some embodiments, “about” may specify the value of a parameter to be between 90% and 110% of the given value. According to some embodiments, “about” may specify the value of a parameter to be between 95% and 105% of the given value.

As used herein, according to some embodiments, the terms “substantially” and “about” may be interchangeable.

According to some embodiments, an estimated quantity or estimated parameter may be said to be “about optimized” or “about optimal” when falling within 5%, 10% or even 20% of the optimal value thereof. Each possibility corresponds to separate embodiments. In particular, the expressions “about optimized” and “about optimal” also cover the case wherein the estimated quantity or estimated parameter is equal to the optimal value of the quantity or the parameter. The optimal value may in principle be obtainable using mathematical optimization software. Thus, for example, an estimated (e.g. an estimated residual) may be said to be “about minimized” or “about minimal/minimum”, when the value thereof is no greater than 101%, 105%, 110%, or 120% (or some other pre-defined threshold percentage) of the optimal value of the quantity. Each possibility corresponds to separate embodiments.

For ease of description, in some of the figures a three-dimensional cartesian coordinate system (with orthogonal axes x, y, and z) is introduced. It is noted that the orientation of the coordinate system relative to a depicted object may vary from one figure to another. Further, the symbol ⊙ may be used to represent an axis pointing “out of the page”, while the symbol ⊗ may be used to represent an axis pointing “into the page”.

In block diagrams dotted lines connecting elements may be used to represent functional association or at least one-way or two-way communicational association between the connected elements.

As used herein, the acronyms “SEM” and “BSE” stand for “scanning electron microscope” and “backscattered electrons”, respectively. “E-beam” stands for “electron beam”.

The present application is directed at BSE measurement-based methods and systems for non-destructively mapping the concentration of one or more substances within a sample: E-beams at each of a plurality of landing energies are projected on the sample. Each e-beam penetrates into the sample and induces backscattering of electrons (in the e-beam) from a respective (probed) region within the sample. The greater the landing energy, the greater the depth about which the probed region is centered.

While BSE measurement data pertaining to a probed region are indicative of the relative (overall) concentrations of substances included in the probed region, these data are not “localized” in the sense that some state-of-the-art applications require mapping resolutions, which are much finer than the dimensions of the probed regions. The present application teaches how BSE measurement data from multiple probed regions centered about multiple depths, respectively, may be jointly processed to obtain a high-resolution concentration map of one or more substances included in a sample (thereby overcoming the above-mentioned problem). According to some embodiments, the processing is performed by a neural network. The present application further discloses methods whereby a neural network may be trained to perform such processing. Advantageously, the present application teaches how to amplify a small set of (measured) ground truth data to obtain an arbitrarily larger set of simulated “ground truth” data, which may be used to train the neural network.

### Depth-Profiling Methods

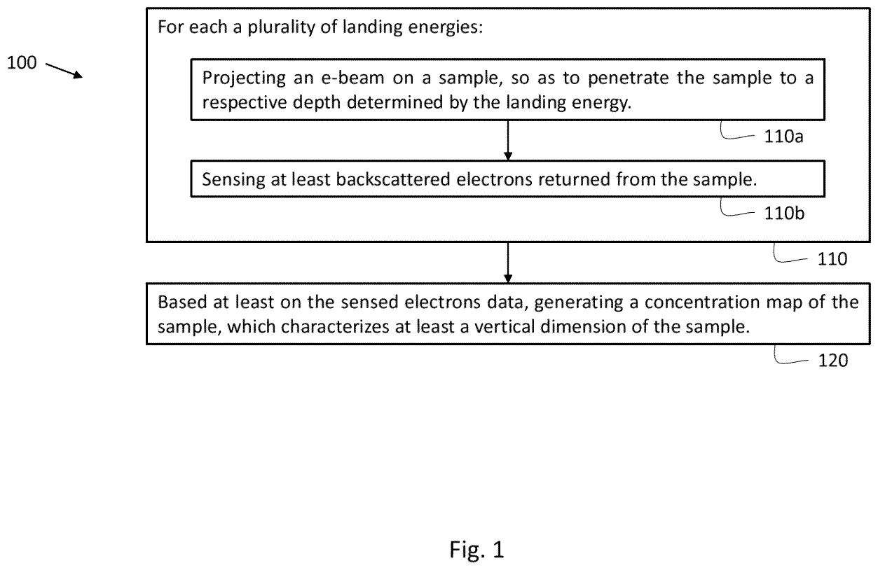

According to an aspect of some embodiments, there is provided a computerized method for non-destructive depth-profiling of samples (e.g. semiconductor structures) based on scanning electron microscopy. FIG. 1 presents a flowchart of such a method, a method 100, according to some embodiments. Method 100 includes:
A measurement operation 110, which includes, for each of a plurality of landing energies, performing:
   A suboperation 110a, wherein an electron beam (e-beam) is projected on a sample, so as to penetrate the sample to a respective depth determined by the landing energy.
   A suboperation 110b, wherein at least backscattered electrons returned from the sample, as a result of the projection thereon of the e-beam, are sensed (i.e. measured), thereby obtaining a respective sensed electrons data set.
A data analysis operation 120, wherein a concentration map of the sample is generated based at least on the sensed electrons data sets (the totality of measurement data obtained by sensing electrons in the implementations of suboperation 110b). The concentration map characterizes at least a vertical dimension of the sample.

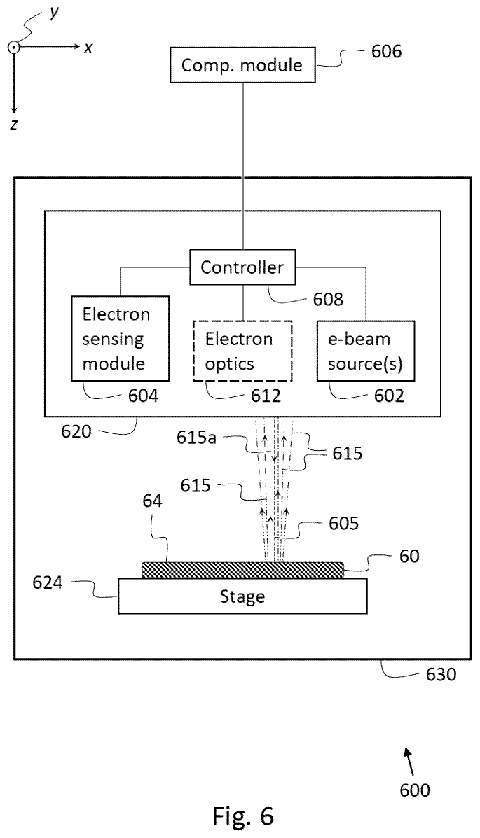

Method 100 may be implemented using a system, such as the system described below in the description of FIG. 6, or systems similar thereto.

According to some embodiments, the concentration map characterizes a dependence on at least the depth of (i) the mass density or relative mass density (i.e. percentage by weight per unit volume) of at least one substance in the sample or (ii) the particle density (e.g. atomic density) or relative particle density (e.g. atomic percent) of substances in the sample. As used herein, the term “particles”, employed in relation to a substance, refers to one or more types of atoms, and/or one or more types of molecules, which the substance is composed of. The term “relative particle density”, employed in relation to a bulk including at least a first substance, refers to the ratio of the number particles—making up the first substance—per unit volume to the total number of particles (i.e. of all substances included in the bulk) per unit volume. According to some alternative embodiments, the concentration map characterizes a dependence on at least the depth of a quantity which is a function of both the mass density and the particle density.

According to some embodiments, at each map coordinate(s), the concentration map specifies a substance, which has the highest density out of all substances present (i.e. found) about the map coordinate(s), that is, (a) in a thin lateral layer vertically centered about the map coordinate (the vertical coordinate) in the one-dimensional case, or (b) in a voxel centered about the map coordinates (i.e. the vertical coordinate and two lateral coordinates) in the three-dimensional case. Thus, each thin layer in the one-dimensional case, and each voxel in the three-dimensional case, is classified according to the substance exhibiting the highest concentration.

Alternatively, according to some embodiments, at each map coordinate(s), the concentration map specifies densities of one or more substances, which the sample includes. According to some such embodiments, each density is specified to within a density range from a plurality of density ranges (or a respective density range from a respective plurality of density ranges, as described in the next paragraph). That is, the density is given by i×Δ, wherein Δ is the magnitude of the ranges (i.e. the density resolution), and i is a non-negative integer.

According to some embodiments, wherein the densities are specified in terms of mass, the density resolution of two different substances (e.g. a light element and a heavy element) may differ: The (mass) density of a first substance may be given by i₁×Δ₁, and the (mass) density of a second substance may be given by i₂×Δ₂, wherein Δ₂≠Δ₁ (reflecting the difference in BSE yields, or equivalently the BSE coefficients, between the two substances).

Suboperation 110b may be implemented using an electron sensor(s) (which may constitute or form part of an electron sensing module, such as the electron sensing module of FIG. 6). According to some embodiments, the electron sensor(s) may be configured to measure the intensity of an e-beam incident thereon (e.g. electrons backscattered towards a BSE detector). In such embodiments, each of the sensed electrons data sets includes at least the intensity of the e-beam sensed in the respective implementation of suboperation 110b. According to some embodiments, the electron sensor may be an electron image sensor (e.g. a BSE image detector). That is, the electron sensor may be configured to obtain a two-dimensional image (which specifies the intensity of electron sub-beams incident on each pixel, respectively, on the electron sensor). In such embodiments, each of the sensed electrons data sets includes at least the intensities of electron sub-beams measured by each pixel on the electron sensor in the respective implementation of suboperation 110b. According to some embodiments, suboperation 110b may be implemented using two or more electron sensors. For example, a first electron sensor (e.g. a first BSE detector) may be positioned so as to collect backscattered electrons returned at a scattering angle of about 180°, while a second electron sensor (e.g. a second BSE detector) may be positioned so as to collect backscattered electrons returned at a scattering angle of about 170°, about 160°, or about 150°. Each possibility corresponds to separate embodiments. In such embodiments, each of the sensed electrons data sets includes at least the intensities of the e-beams measured by each of the electron sensors in the respective implementation of suboperation 110b.

According to some embodiments, in suboperation 110b, in addition to backscattered electrons, secondary electrons (returned from the sample) are also sensed, thereby obtaining a respective sensed secondary electrons data set. In such embodiments, in data analysis operation 120, the sensed secondary electrons data sets are additionally taken into account in generating the concentration map.

According to some embodiments, the design intent (i.e. the intended design) of the sample is known and is used to obtain the concentration map of the sample in data analysis operation 120. In particular, method 100 may be used to validate the distributions of the one or more substances within a sample. More specifically, method 100 may be used to quantify small variations (e.g. to within 1%, 3%, or even 5%) from a nominal distribution (specified by the design intent) of a substance in a sample. According to some embodiments, at each map coordinate(s), and for each profiled substance, the concentration map may specify the difference in the density of the profiled substance relative to the nominal density thereof (which may be specified in terms of mass density, relative mass density, particle density, or relative particle density). According to some such embodiments, the differences may be specified to within difference intervals. According to some embodiments, at each map coordinate(s), and for each profiled substance, the concentration map may specify the actual density of the profiled substance (which may be specified in terms of mass density, relative mass density, particle density, or relative particle density)—i.e. the density computed in data analysis operation 120. According to some such embodiments, the actual densities may be specified to within density ranges.

According to some embodiments, reference data, pertaining to the sample, may be used in obtaining the concentration map of the sample in data analysis operation 120. As used herein, the term “reference data” may refer to structural information of a sample, which is initially available (i.e. prior to implementing method 100). The structural information may include design data (i.e. specifying the design intent) of the sample and/or measured structural data, which is obtained by profiling other samples of the same design intent as the sample (which is to be profiled using method 100) or even samples from the same batch (e.g. when the sample is a wafer) as the sample. Measured structural data may slightly vary from design data in additionally reflecting systemic production imperfections.

According to some embodiments, the sample is a patterned wafer, a part of a patterned wafer, or a semiconductor structure included in a patterned wafer. According to some such embodiments, the sample may be or include one or more logic components (e.g. a fin FET (FinFET) and/or a gate-all-around (GAA) FET) and/or memory components (e.g. a dynamic RAM and/or a vertical NAND (V-NAND)).

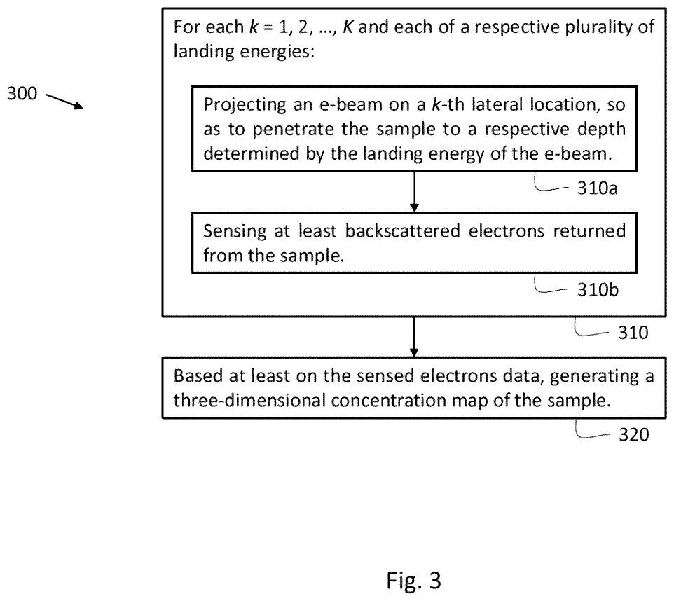

Method 100 may be used to provide a one-dimensional concentration map of a sample or a three-dimensional concentration map of a sample (or a two-dimensional concentration map of a sample). Each possibility corresponds to separate embodiments. In the latter case (i.e. in embodiments wherein method 100 is used for three-dimensional profiling of a sample), and as described in detail below in the description of FIGS. 3-5, measurement operation 110 is serially implemented with respect to each of a plurality of (lateral) locations on the sample (e.g. on a top surface thereof).

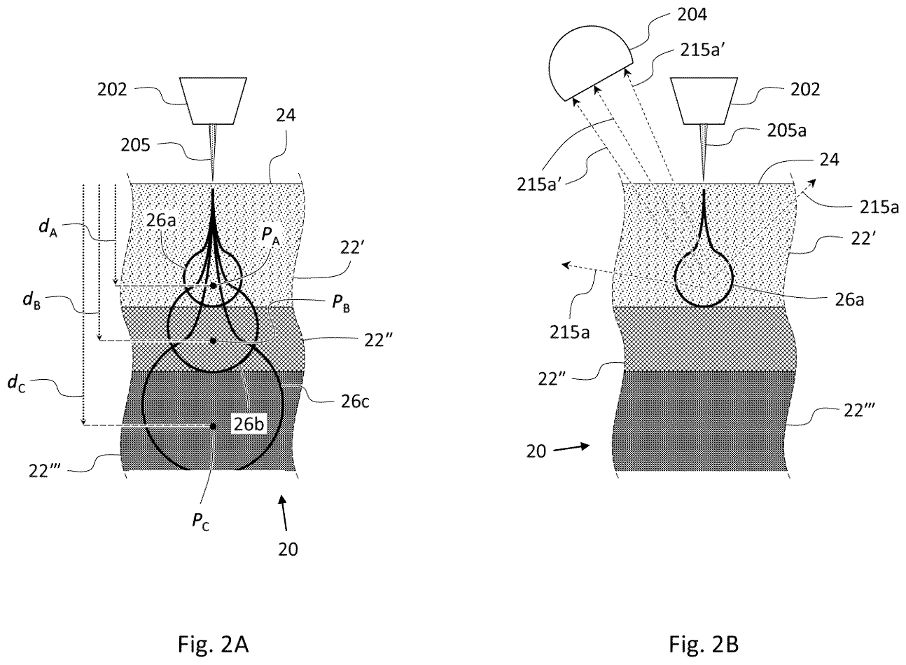

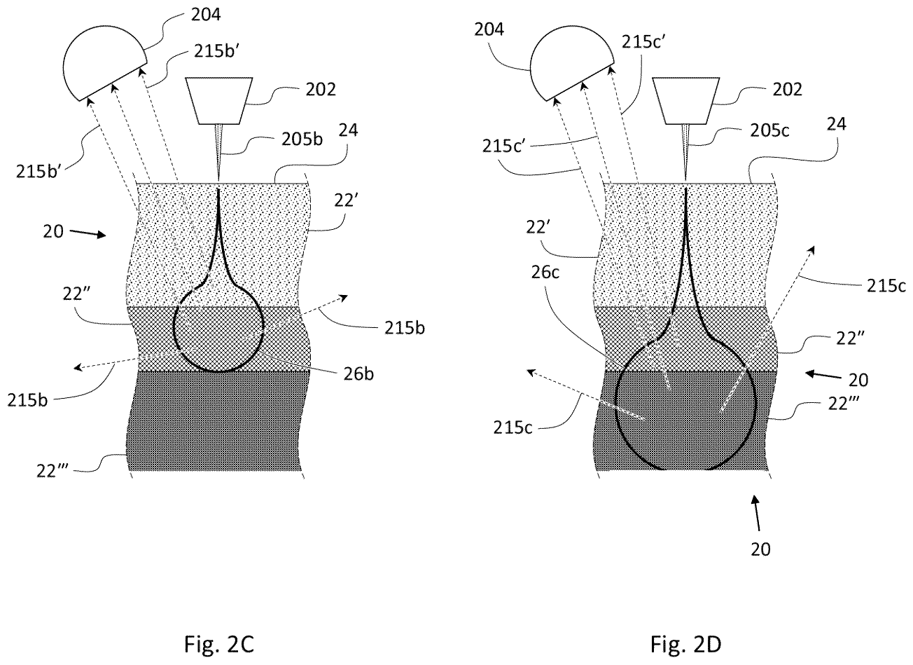

First, the one-dimensional case is described in detail. To this end, reference is additionally made to FIGS. 2A-2D. FIGS. 2A-2D schematically depict an implementation of measurement operation 110 of method 100, according to some embodiments thereof, wherein a one-dimensional concentration map of a sample is to be obtained.

FIG. 2A shows a cross-sectional view of a sample 20 being probed by an e-beam in accordance with measurement operation 110. Sample 20 may include a plurality of lateral (i.e. horizontal) layers 22. To facilitate the description, it is assumed that at least some of layers 22 differ from one another in material composition (i.e. differ in constituents or, when including the same constituents, differ in the concentrations of the constituents). According to some embodiments, at least some of layers 22 may differ from one another in thickness.

To ease the description, as a non-limiting example, in FIGS. 2A-2D sample 20 is shown as including three layers disposed one on top of the other: a first layer 22′ (from layers 22), a second layer 22″ (from layers 22), and a third layer 22′″ (from layers 22). First layer 22′ is disposed above second layer 22″. Second layer 22″ is sandwiched between first layer 22′ and third layer 22′″. The top surface of first layer 22′ constitutes an external surface 24 of sample 20. Also shown is an e-beam source 202 and an e-beam 205 produced thereby, so as to impinge (e.g. normally impinge) on external surface 24. E-beam source 202 may be configured to project e-beams (one at a time) at each of a plurality of landing energies, thereby implementing sub operation 110a.

The greater the landing energy of e-beam 205, the greater the depth to which electrons from e-beam 205 will (on average) penetrate into sample 20. Further, the greater the landing energy of e-beam 205, the greater may be the volume within sample 20 wherein electrons from e-beam 205 elastically interact with matter in sample 20 so as to be reflected. This is exemplified in FIG. 2A via three probed regions 26: A first probed region 26a corresponds to the volume of sample 20 in which about all (e.g. at least 80%, at least 90%, or at least 95%) of the elastic interactions—which lead to the backscattering of electrons in a penetrating e-beam having a first landing energy E₁—will occur. A second probed region 26b corresponds to the volume of sample 20 in which about all of the elastic interactions—which lead to the backscattering of electrons in a penetrating e-beam having a second landing energy E₂—will occur. A third probed region 26c corresponds to the volume of sample 20 in which about all of the elastic interactions—which lead to the backscattering of electrons in a penetrating e-beam having a third landing energy E₃—will occur. First probed region 26a is centered about a first point P_{A} at a depth d_{A}, second probed region 26b is centered about a second point P_{B} at a depth d_{B}, and third probed region 26c is centered about a third point P_{C} at a depth d_{C}. E₁<E₂<E₃. Accordingly, d_{A}<d_{B}<d_{C}. According to some embodiments, and as depicted in FIG. 2A, third probed region 26c is of a greater size than second probed region 26b, which is of a greater size than first probed region 26a.

The required depth resolution of the concentration map dictates the number of landing energies. In particular, the greater the required depth resolution, the greater the number of landing energies used. Accordingly, the distances between centers of successive (probed) regions (e.g. the distance d_{B}−d_{A} between P_{A} and P_{B}, the distance d_{C}−d_{B} between P_{B} and P_{C}) are dictated by the required depth resolution of the concentration map. According to some embodiments, the depth resolution is selected to be sufficiently high to detect and “pin-point” changes in the concentration. For example, in the (one-dimensional) depth-profiling of sample 20, the depth resolution may be selected to be greater than the thickness of the thinnest of layers 22.

FIG. 2B shows a first e-beam 205a—generated by e-beam source 202 and having the first landing energy E₁—incident on sample 20. Also delineated is first probed region 26a (from which about all of the backscattered electrons are reflected). The backscattered electrons are indicated by arrows 215a. Arrows 215a′ indicate a fraction (i.e. portion) of these backscattered electrons, which are reflected towards an electron sensing module 204.

FIG. 2C shows a second e-beam 205b—generated by e-beam source 202 and having the second landing energy E₂—incident on sample 20. Also delineated is second probed region 26b (from which about all of the backscattered electrons are reflected). The backscattered electrons are indicated by arrows 215b. Arrows 215b′ indicate a fraction of these backscattered electrons, which are reflected towards (and arrive at) electron sensing module 204.

FIG. 2D shows a third e-beam 205c—generated by e-beam source 202 and having the third landing energy E₃—incident on sample 20. Also delineated is third probed region 26c (from which about all of the backscattered electrons are reflected). The backscattered electrons are indicated by arrows 215c. Arrows 215c′ indicate a fraction of these backscattered electrons, which are reflected towards (and arrive at) electron sensing module 204.

According to some embodiments, electron sensing module 204 may be or include a BSE detector. According to some embodiments, not depicted in FIGS. 2B-2D, electron sensing module 204 may include two or more BSE detectors.

For each landing energy (e.g. landing energies E₁, E₂, and E₃), a respective intensity of electrons, returned from sample 20 onto electron sensing module 204, is measured by electron sensing module 204, thereby implementing suboperation 110b. The intensity of an e-beam returned from a probed region is indicative of the material composition of the probed region. By sensing (backscattered) electrons in returned e-beams induced by each of a sufficiently large plurality of e-beams at a plurality of (different) landing energies, respectively, and subjecting the thus-obtained sensed electrons data sets to a joint analysis (for example, using a machine learning (ML) derived algorithm as described below), a dependence of the material composition on the depth may be extracted (in data analysis operation 120). More specifically, since the presence and spatial distribution of each substance generally gives rise to a unique contribution to the (differential) elastic scattering cross-section, by probing a sample to a plurality of depths (by impinging the sample, one at a time, with e-beams of different landing energies), information indicative of the material composition of the sample as a function of the depth may be obtained.

According to some embodiments, the concentration map specifies, for each of a plurality of map coordinate(s) (e.g. in the one-dimensional case, thin layers, each centered about a respective map coordinate, in the three-dimensional case, voxels, each centered about respective map coordinates), the substance that has the highest concentration out of the substances present about the map coordinate(s). According to some embodiments, the concentration map specifies, for each map coordinate(s), the concentrations of each of a plurality of substances included in the sample. According to some such embodiments, each concentration is specified to a respective density range from a plurality, or a respective plurality, of density ranges. Alternatively, according to some embodiments, each concentration is specified to a respective numerical value (from a continuum of (density) values).

According to some embodiments, the concentration map may be obtained as the output of a NN. The NN is configured to receive as inputs the sensed electrons data sets—obtained in measurement operation 110—labelled by the landing energies of the respective e-beams.

According to some embodiments, wherein at each map coordinate(s) the concentration map (output by the NN) specifies the substance having the highest concentration about the map coordinate(s), the NN is a classification NN.

According to some embodiments, wherein at each map coordinate(s) the concentration map specifies the concentrations of substances, included in the sample, to within density ranges, the NN may be a classification NN. That is, in such embodiments, the NN may be configured to assign the concentration of a substance in a subregion (e.g. thin layer or voxel)—centered about a map coordinate(s)—to a respective density range from a plurality of density ranges. The density ranges may be complimentary in the sense of jointly constituting a continuous range of densities.

According to some embodiments, wherein at each map coordinate(s) the concentration map specifies the concentration of each substance to a respective numerical value, the NN may be a regression NN.

According to some embodiments, wherein the NN is a classification NN, the NN may be a convolutional NN (CNN).

According to some embodiments, the NN may be a generative adversarial network (GAN).

According to some embodiments, wherein the NN is a classification NN, the NN may be composed of a variational autoencoder (VAE) and a classifier (for example, a support vector machine (SVM) or a deep NN). In such embodiments, the sensed electrons data sets (without labelling) are input into the VAE, which is configured to extract therefrom latent variables. The latent variables serve as inputs to the classifier, which is configured to output the concentration map. Alternatively, according to some embodiments, the NN may be a multi-head VAE.

According to some embodiments, wherein the NN is a classification NN, the NN may be an AlexNet, a VGG NN, or a ResNet.

The Training Methods Subsection below describes various ways whereby a NN may be trained to correlate sensed electrons data sets of a sample, obtained for a plurality of e-beam at a plurality of landing energies, to the material composition of the sample.

FIG. 3 presents a flowchart of a method 300 for three-dimensional depth-profiling of samples. Method 300 corresponds to specific embodiments of method 100. Method 300 includes:
A measurement operation 310, wherein, for each (integer) k from 1 to K, and for each of a respective plurality of landing energies (that is, different k may have associated therewith different pluralities of landing energies, respectively, which may differ in values and in number):
   A suboperation 310a, wherein an e-beam is projected on a sample on a k-th lateral location on the sample, so as to penetrate the sample to a respective depth determined by the landing energy of the e-beam.
   A suboperation 310b, wherein electrons returned from the sample, as result of the projection thereon of the e-beam, are sensed, thereby obtaining a respective sensed electrons data set.
A data analysis operation 320, wherein a three-dimensional concentration map of the sample is generated based at least on the sensed electrons data sets (obtained by projecting the e-beams on each of the K lateral locations).

The skilled person will readily perceive that the order at which the above operations and suboperations are listed is not unique. Other applicable orders are also covered by the present disclosure. For example, according to some embodiments, data analysis operation 320 may be commenced prior to the conclusion of measurement operation 310. The skilled person will further perceive that method 300 may also be employed to obtain a two-dimensional (defined by the depth dimension and at least one lateral dimension) concentration map of a sample.

Suboperation 310b may be implemented using one or more electron sensors (e.g. which may constitute or form part of an electron sensing module, such as the electron sensing module of FIG. 6). According to some embodiments, the electron sensor is an electron image sensor (e.g. a BSE image detector). In such embodiments, each of the sensed electrons data sets includes at least the measured intensities of electron sub-beams incident on each pixel on the electron image sensor in the respective implementation of suboperation 310b. According to some embodiments, suboperation 310b may be implemented using two or more electron sensors and/or image sensors. In such embodiments, each of the sensed electrons data sets includes at least the intensities of the e-beams measured by each of the electron sensors, or by each pixel on each of the electron image sensors, in the respective implementation of suboperation 310b.

In data analysis operation 320, sensed electrons data sets of probed regions, which are laterally displaced with respect to a given probed region (e.g. laterally adjacent to the given probed region), are additionally taken into account in determining the distributions of the substances within the given probed region. The di stance(s) between adjacent lateral locations is dictated by the required lateral resolution of the concentration map.

According to some embodiments, the design intent (i.e. the intended design) of the sample is known and is used to obtain the concentration map of the sample in data analysis operation 320. In particular, method 300 may be used to validate the distributions of one or more substances within a sample, essentially as described above in the description of method 100.

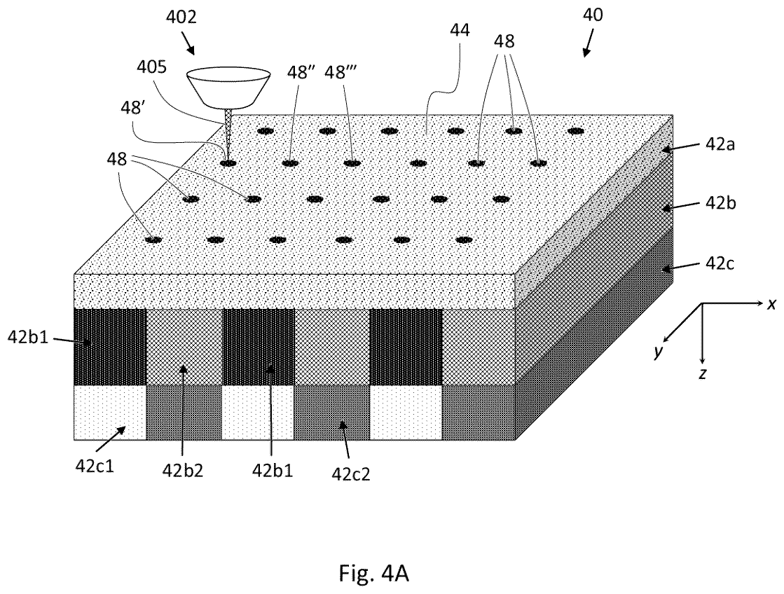

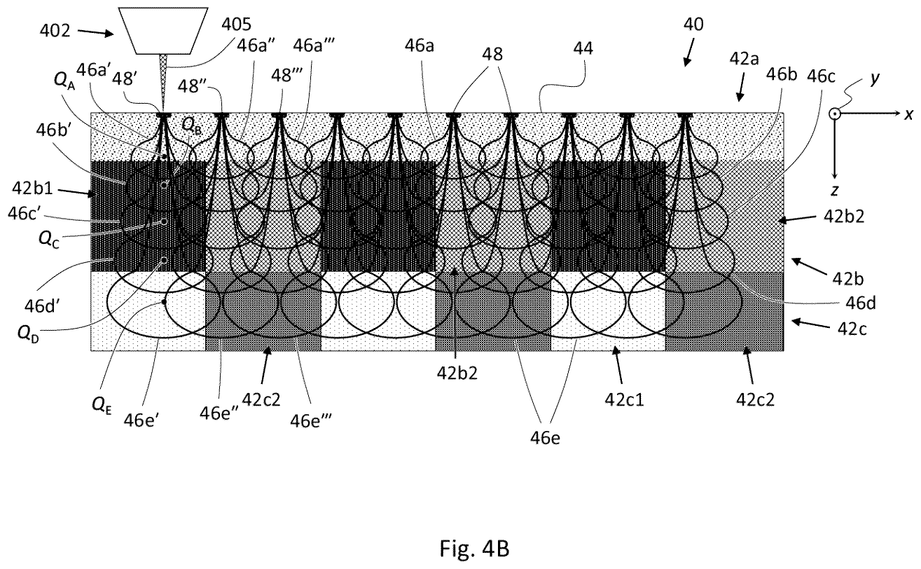

To facilitate the description, in addition to FIG. 3, reference is also made to FIGS. 4A and 4B, which schematically depict an implementation of method 300, according to some embodiments thereof. FIG. 4A shows a perspective view of a sample 40 being probed by an e-beam in accordance with measurement operation 310. Sample 40 may include a plurality of layers 42. To facilitate the description, it is assumed that at least some of layers 42 differ from one another in material composition. According to some embodiments, at least some of layers 42 may differ from one another in dimensions thereof. According to some embodiments, at least some of layers 42 may differ from one another in internal geometries thereof. According to some embodiments, at least some of layers 42, which include the same constituents (i.e. substances), differ from one another in the distributions of the constituents therein. According to some such embodiments, wherein layers 42 are shaped, or nominally shaped, as horizontally disposed slabs, at least some of layers 42 may differ from one another in thickness.

As a non-limiting example, in FIG. 4A sample 40 is shown as including three layers disposed one on top of the other: a first layer 42a (from layers 42), a second layer 42b (from layers 42), and a third layer 42c (from layers 42). First layer 42a is disposed above second layer 42b. Second layer 42b is sandwiched between first layer 42a and third layer 42c. The top surface of first layer 42a constitutes an external surface 44 of sample 40.

As depicted in FIGS. 4A and 4B, second layer 42b may be non-uniform by design and may include two types of segments: first segments 42b1 and second segments 42b2 (not all of which are numbered in FIGS. 4A and 4B). Each of first segments 42b1 and each of second segments 42b2 extends in parallel to the y-axis. First segments 42b1 and second segments 42b2 are alternately disposed. According to some embodiments, first segments 42b1 differ from second segments 42b2 in the material composition thereof, whether in terms of constituents (i.e. substances included therein) and/or densities of same constituents. According to some embodiments, first segments 42b1 may be composed of a first semiconductor material (i.e. semiconductor substance) and second segments 42b2 may be composed of a second semiconductor material.

Similarly, and as depicted in FIGS. 4A and 4B, third layer 42c may be non-uniform by design and may include two types of segments: third segments 42c1 and fourth segments 42c2 (not all of which are numbered in FIGS. 4A and 4B). Each of third segments 42c1 and each of fourth segments 42c2 extends in parallel to they-axis. Third segments 42c1 and fourth segments 42c2 are alternately disposed. According to some embodiments, third segments 42c1 differ from fourth segments 42c2 in the material composition thereof, whether in terms of constituents and/or densities of same constituents. According to some embodiments, third segments 42c1 may be composed of a third semiconductor material and fourth segments 42c2 may be composed of a fourth semiconductor material. According to some embodiments, and as depicted in FIGS. 4A and 4B, third segments 42c1 are positioned below first segments 42b1, respectively, and fourth segments 42c2 are positioned below second segments 42b2, respectively.

Also shown is an e-beam source 402. E-beam source 402 may be configured to project e-beams (one at a time) on each of a plurality of (lateral) locations 48 (not all of which are numbered) on external surface 44. For example, in FIG. 4A e-beam source 402 is shown generating an e-beam 405, which impinges (e.g. normally impinges) on external surface 44 at a location 48′ (from locations 48). At least some of the e-beams projected on the same location differ from one another in landing energy, so that sample 40 is probed (beneath location 48′) at a plurality of depths. According to some embodiments, locations 48 may be so distributed so as to define a lattice, for example, a square lattice.

Referring also to FIG. 4B, FIG. 4B presents a cross-sectional view of sample 40 that shows probed regions 46 therein, according to some embodiments of method 300, and, in particular, measurement operation 310. As a non-limiting example intended to facilitate the description by making it more concrete, in FIG. 4B at each of locations 48 e-beams at five landing energies are applied. According to some embodiments, each of probed regions 46a corresponds to a respective volume from which about all (e.g. at least 80%, at least 90%, or at least 95%) of the backscattered electrons are reflected as a result of the penetration of a respective e-beam at a respective first landing energy into sample 40 via a respective location from locations 48. For example, a first probed region 46a′ corresponds to the volume from which about all of the backscattered electrons are reflected as a result of the penetration of an e-beam at a first landing energy E₁′ into sample 40 via a location 48′ (from locations 48).

Each of probed regions 46b corresponds to a respective volume from which about all of the backscattered electrons are reflected as a result of the penetration of a respective e-beam at a respective second landing energy (greater than the respective first landing energy) into sample 40 via a respective location from locations 48. For example, a second probed region 46b′ corresponds to the volume from which about all of the backscattered electrons are reflected as a result of the penetration of an e-beam at a second landing energy E₂′>E₁′ into sample 40 via location 48′.

Each of probed regions 46c corresponds to a respective volume from which about all of the backscattered electrons are reflected as a result of the penetration of a respective e-beam at a respective third landing energy (greater than the respective second landing energy) into sample via a respective location from locations 48. For example, a third probed region 46c′ corresponds to the volume from which about all of the backscattered electrons are reflected as a result of the penetration of an e-beam at a third landing energy E₃′>E₂′ into sample 40 via location 48′.

Each of probed regions 46d corresponds to a respective volume from which about all of the backscattered electrons are reflected as a result of the penetration of a respective e-beam at a respective fourth landing energy (greater than the third landing energy) into sample 40 via a respective location from locations 48. For example, a fourth probed region 46d′ corresponds to the volume from which about all of the backscattered electrons are reflected as a result of the penetration of an e-beam at a fourth landing energy E₄′>E₃′ into sample 40 via location 48′.

Each of probed regions 46e corresponds to a respective volume from which about all of the backscattered electrons are reflected as a result of the penetration of a respective e-beam at a respective fifth landing energy (greater than the fourth landing energy) into sample 40 via a respective location from locations 48. For example, a fifth probed region 46e′ corresponds to the volume from which about all of the backscattered electrons are reflected as a result of the penetration of an e-beam at a fifth landing energy E₅′>E₄′ into sample 40 via location 48′.

First probed region 46a′ is centered about a first point Q_{A} at a depth b_{A}, second probed region 46b′ is centered about a second point Q_{B} at a depth b_{B}, third probed region 46c′ is centered about a third point Q_{C} at a depth b_{C}, fourth probed region 46d′ is centered about a fourth point Q_{D} at a depth b_{D}, and fifth probed region 46e′ is centered about a fifth point Q_{E} at a depth b_{E}. E₁′<E₂′<E₃′<E₄′<E₅′. Accordingly, b_{A}<b_{B}<b_{C}<b_{D}<b_{E}. According to some embodiments, and as depicted in FIG. 4B, fifth probed region 46e′ is of a greater size than fourth probed region 46d′, which is of a greater size than third probed region 46c′, which is of a greater size than second probed region 46b′, which is of a greater size than first probed region 46a′.

Also indicated are a location 48″ and a location 48′″ (from locations 48). Each of locations 48′ and 48′″ is adjacent to location 48″, which is positioned there between. A probed region 46a″, from probed regions 46a, corresponds to the volume from which about all of the backscattered electrons are reflected as a result of the penetration of an e-beam at a respective first landing energy into sample 40 via location 48″. A probed region 46e″, from probed regions 46e, corresponds to the volume from which about all of the backscattered electrons are reflected as a result of the penetration of an e-beam at a respective fifth landing energy into sample 40 via location 48″. A probed region 46a′″, from probed regions 46a, corresponds to the volume from which about all of the backscattered electrons are reflected as a result of the penetration of an e-beam at a respective first landing energy into sample 40 via location 48′″. A probed region 46e′″, from probed regions 46e, correspond to the volume from which about all of the backscattered electrons are reflected as a result of the penetration of an e-beam at a respective fifth landing energy into sample 40 via location 48′″.

It is noted that since sample 40 is not uniform along the direction defined by the x-axis, sets of landing energies of e-beams applied at locations which differ in their x-coordinates may differ. Thus, for example, since location 48′ is positioned above one of first segments 42b1 and one of third segments 42c1, while location 48′″ is positioned above one of second segments 42b2 and one of fourth segments 42c2, according to some embodiments, {E₁′″}ᵢ₌₁⁵≠{Eᵢ′}ᵢ₌₁⁵, wherein {Eᵢ′″}ᵢ₌₁⁵ is the set of landing energies corresponding to e-beams applied via location 48′″ (and {Eᵢ′}ᵢ₌₁⁵ is the set of landing energies corresponding to e-beams applied via location 48′).

Example embodiments—wherein sets of landing energies may be selected to differ from one another depending on the respective lateral locations on which the e-beams are projected—are when first segments 42b1 are denser than second segments 42b2, so that in order to penetrate first segments 42b1 to the same depth as second segments 42b2, a greater landing energy may be required. If, in addition, third segments 42c1 are denser than fourth segments 42c2, in order to ensure that sample 40 is probed to about the same depth beneath each of location 48′ and 48″, for each i, Eᵢ′ may be greater than Eᵢ′″. Other example embodiments—wherein sets of landing energies may be selected to differ from one another depending on the respective lateral locations on which the e-beams are projected—are when first segments 42b1 and third segments 42c1 are less electrically conducting than second segments 42b2 and fourth segments 42c2, respectively.

The distances between adjacent locations from locations 48 (and therefore the distances between the centers of laterally adjacent probed regions) are selected based on the required lateral resolution (which may or may not be equal to the required vertical resolution). It is noted that while in FIG. 4B laterally adjacent probed regions are shown as overlapping, depending on the required lateral resolution, according to some other embodiments, some laterally adjacent probed regions (centered about smaller depths), or even all laterally adjacent probed regions, may not overlap. According to some embodiments, the lateral resolution is selected to be sufficiently high to detect and “pin-point” changes in the concentration of the profiled constituent(s). Accordingly, the distance between adjacent lateral locations (from lateral location 48) may be selected to be smaller than the width of first segments 42b1 as well as the width of second segments 42b2.

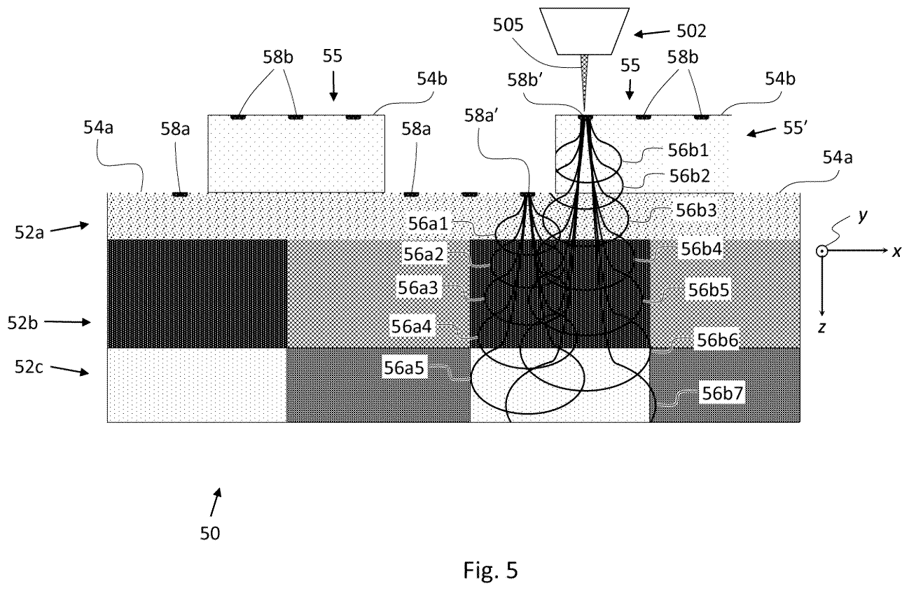

While in FIGS. 4A and 4B external surface 44 is depicted as flat, it is to be understood that method 300 may be applied to samples, which do not have a flat top surface. In particular, method 300 may be applied to samples whose top surface includes areas at different elevations. FIG. 5 depicts an implementation of method 300 to such a sample, a sample 50, according to some embodiments. As a non-limiting example, sample 50 is shown as including a first layer 52a, a second layer 52b, and a third layer 52c, which are disposed one on top of the other. Sample 50 further includes projecting structures 55, which are positioned on top of first layer 51 and project therefrom in the direction of the negative z-axis. Projecting structures 55 jointly have smaller lateral dimensions than first layer 52a, so that a top surface of sample 50, constituted by an external surface 54, includes two (discontinuous) lateral surfaces of different elevation: a first surface 54a and a second surface 54b. First surface 54a constitutes the top external surface of first layer 52a. Second surface 54b includes the top surfaces of projecting structures 55. According to some embodiments, projecting structures 55 may have a different material composition than any of layers 52a, 52b, and 52c.

Also shown is an e-beam source 502 and an e-beam 505 produced thereby, so as to impinge (e.g. normally impinge) on external surface 54. First lateral locations 58a (not all of which are numbered) on first surface 54a indicate locations at which, in operation 310, e-beams projected by e-beam source 502 strike first surface 54a (so as to probe layers 52a, 52b, and 52c there beneath). Second lateral locations 58b on second surface 54b indicate locations at which, in operation 310, e-beams projected by e-beam source 502 strike second surface 54b (so as to probe projecting structures 55 and layers 52a, 52b, and 52c there beneath). E-beams having a first set of landing energies may be directed at each of first lateral locations 58a, respectively, and e-beams having a second set of landing energies may be directed at each of second lateral locations 58b, respectively. In order to probe sample 50 to the full depth thereof beneath both first surface 54a and second surface 54b and to the same resolution, the second set of landing energies may generally be larger than the first set of landing energies (i.e. the number of landing energies in the second set may generally be greater than the number of landing energies in the first set).

Accordingly, delineated in FIG. 5 are (i) five probed regions 56a1, 56a2, 56a3, 56a4, and 56a5 centered below a lateral location 58a′ from first lateral locations 58a, and (ii) seven probed regions 56b1, 56b2, 56b3, 56b4, 56b5, 56b6, and 56b7 centered below a lateral location 58b′ (from second lateral locations 58b) on a projecting structure 55′ (from projecting structure 55). Probed regions below the rest of first lateral locations 58a and second lateral locations 58b are not delineated. Probed region 56b1 is confined within projecting structure 55′, while probed region 56b2 penetrates into first layer 52a but the center thereof is located in projecting structure 55′. The centers of probed regions 56b3, 56b4, 56b5, 56b6, and 56b7 are located within a respective one of layers 52a, 52b, and 52c.

It is to be understood that the applicability of methods 100 and 300 is not limited to samples including nominally flat layers. Regions differing from one another in material composition (whether in terms of constituents or, when including the same constituents. in the concentrations of the constituents) may in principle be arbitrarily shaped. In particular, method 100 may be performed on a sample characterized by continuously varying concentrations as a function of the depth coordinate (i.e. the vertical coordinate), of one or more of the substances included in the sample. Similarly, method 300 may be performed on a sample characterized by continuously varying concentrations as a function of the depth coordinate, and/or one or both of the lateral coordinates, of one or more of the substances included in the sample. Further, the skilled person will readily perceive that method 100, and, particularly, method 300, may be applied to (i.e. performed on) samples including empty cavities and/or holes.

### Depth-Profiling Systems

According to an aspect of some embodiments, there is provided a computerized system for depth-profiling of samples (e.g. patterned wafers and/or semiconductor structures therein or thereon). FIG. 6 schematically depicts such a system, a computerized system 600, according to some embodiments. As will be apparent from the description thereof, system 600 may be used to implement each of methods 100 and 300. In particular, system 600 may be used to validate the (nominal) concentrations one or more substances in a sample, as described above in the descriptions of systems 100 and 300.

System 600 includes an e-beam source 602 (e.g. an electron gun), an electron sensing module 604, a computational module 606, and a controller 608. According to some embodiments, system 600 may further include electron optics 612 configured to direct and/or focus an e-beam generated by e-beam source 602, and/or direct electrons (e.g. onto an electron sensor) scattered from a sample due to the irradiation thereof with the e-beam. According to some embodiments, and as depicted in FIG. 6, e-beam source 602, electron sensing module 604, electron optics 612, and controller 608 may constitute components of a SEM 620. According to some embodiments, system 600 may further include a stage 624 (e.g. a xyz stage) configured to accommodate an inspected sample 60 (e.g. a patterned wafer). It is noted that sample 60 does not form part of system 600.

Dotted lines between elements indicate functional or communicational association between the elements.

An e-beam 605, generated by e-beam source 602, is shown incident on sample 60. As a result of the incidence of e-beam 605 on sample 60, and penetration of e-beam 605 into sample 60, backscattered electrons, as well as secondary electrons, are returned from sample 60. E-beams 615 indicates backscattered electrons, as well as secondary electrons, which are scattered from sample 60 in the direction of electron sensing module 604. According to some embodiments, electron sensing module 604 may be configured to sense electrons returned at 180° relative to the incidence direction thereof of e-beam 605). E-beam 615a indicate a portion of e-beams 615, which is returned at 180° relative to the incidence direction thereof (i.e. oppositely to e-beam 605).

Electron sensing module 604 may include one or more electron sensors (e.g. BSE detectors), which are configured to sense electrons returned from sample 60 (e.g. backscattered electrons). According to some embodiments, at least one of the one or more electron sensors may be a BSE image detector configured to obtain a BSE image. Electron sensing module 604 is configured to relay (optionally, via controller 608) the data collected thereby (e.g. the measured intensities of e-beams incident on each of the electron sensors, or when the electron sensor is an electron image sensor, the images obtained thereby) to computational module 606.

According to some embodiments, electron optics 612 may include an electrostatic lens(es) and a magnetic deflector(s), which may be used to guide and manipulate an e-beam generated by e-beam source 602, and/or guide onto electron sensing module 604 at least backscattered electrons generated due to the penetration of an e-beam into sample 60.

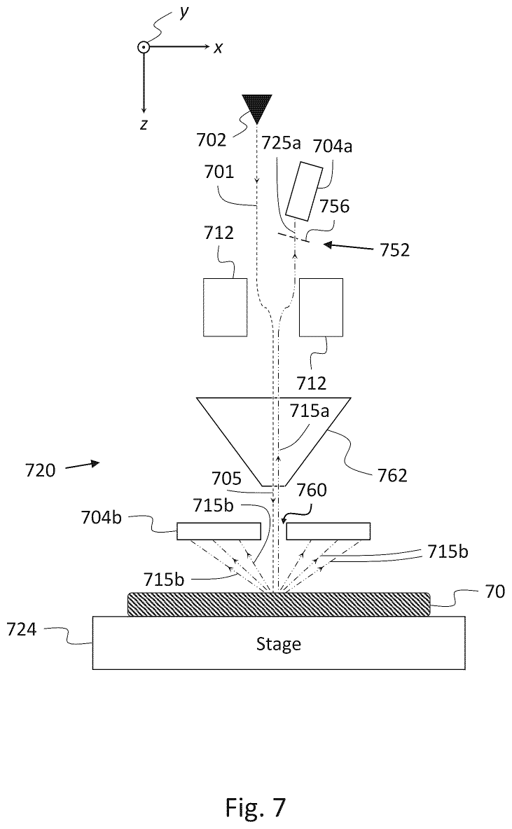

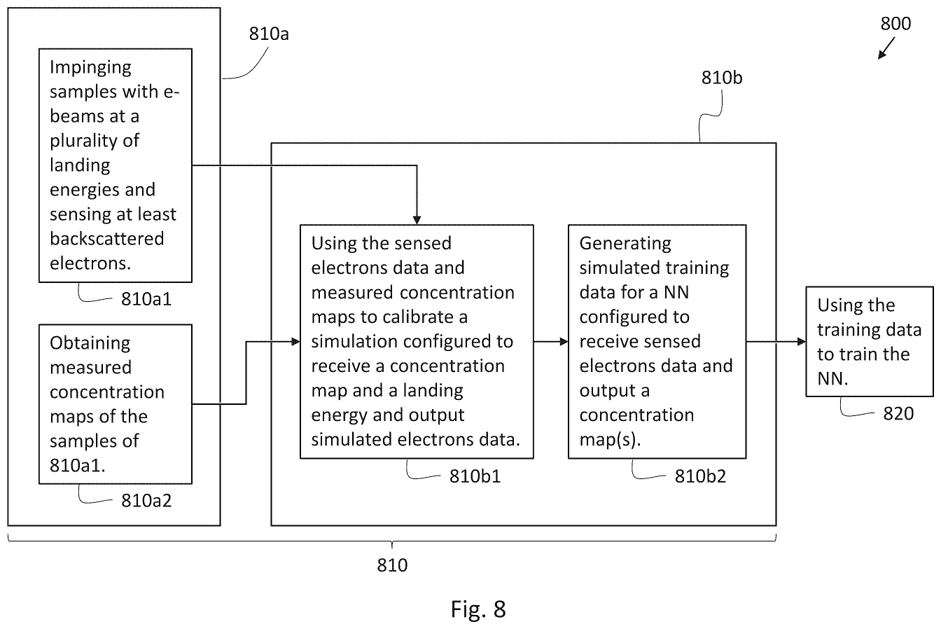

According to some embodiments, electron optics 612 may include an energy filter configured to transmit therethrough onto electron sensing module 604—or onto an electron sensor included in electron sensing module 604, when electron sensing module 604 includes a plurality of electron sensors—electrons having an energy above a threshold energy. More specifically, only electrons with energies higher than the energy threshold pass through the energy filter and reach the sensor, thereby ensuring that substantially only electrons elastically scattered off matter in the sample are sensed by the sensor. A non-limiting example of such a filter, according to some embodiments, is described below in the description of FIG. 7. According to some alternative embodiments, electron optics 612 may include a Wien filter.

According to some embodiments, SEM 620 and stage 624 may be housed within a vacuum chamber 630.

Controller 608 may be functionally associated with e-beam source 602 and, optionally, stage 624. More specifically, controller 608 is configured to control and synchronize operations and functions of the above-listed modules and components during profiling of an inspected sample. For example, according to some embodiments, wherein stage 624 is movable, stage 624 may be configured to mechanically translate an inspected sample (e.g. sample 60), placed thereon, along a trajectory set by controller 608, thereby allowing for three-dimensional profiling of the sample.

Computational module 606 may include computer hardware (one or more processors, and RAM, as well as non-volatile memory components; not shown). The computer hardware is configured to process data, measured (sensed) by electron sensing module 604, to obtain a concentration map of a sample (e.g. sample 60), essentially as described above in the Depth-Profiling Methods Subsection. According to some embodiments, at each map coordinate(s) (i.e. in the one-dimensional case, the vertical coordinate, and, in the three-dimensional case, the vertical coordinate and the two lateral coordinates), the concentration map specifies the substance having the highest density about the map coordinate(s), as described above in the Depth-Profiling Methods Subsection. According to some embodiments, at each map coordinate(s), the concentration map specifies the densities of substances, included in the sample, to within respective density ranges, as described above in the Depth-Profiling Methods Subsection. That is, in such embodiments, computational module 606 may be configured to assign the density of each of one or more substances included in a subregion about the map coordinate(s) (i.e. in the one-dimensional case, a thin lateral layer vertically centered about the vertical coordinate, and, in the three-dimensional case, a subregion (i.e. voxel) centered about the map coordinates) to a respective density range from a plurality, or a respective plurality, of (complementary) density ranges.

Alternatively, according to some embodiments, at each map coordinate(s)s, the concentration map specifies the densities of a substance in terms of a (single) numerical value, as described above in the Depth-Profiling Methods Subsection.

According to some embodiments, the computer hardware may be configured to execute an ML derived algorithm(s), which is configured to receive as inputs sensed electrons data sets of a sample (e.g. obtained by system 600) and to output a concentration map of the sample, as described above in the Depth-Profiling Methods Subsection. According to some embodiments, the ML derived algorithm (e.g. the architecture thereof when the ML derived algorithm is a NN) may depend on design data (specifying the design intent) of the sample, and, more generally, according to some embodiments, reference data of the sample. Alternatively, according to some embodiments, the ML derived algorithm may be configured to receive as inputs—in addition to the sensed electrons data sets—design data of the sample, and, more generally, according to some embodiments, reference data of the sample. According to some embodiments, each of the sensed electrons data sets may be labelled by the corresponding landing energies, respectively, and, when, the concentration map is three-dimensional, the lateral locations at which the respective inducing e-beams impinged on the sample.

According to some embodiments, the ML derived algorithm may be a NN. According to some embodiments, the NN may be a deep NN (for example, a CNN or a fully connected NN).

According to some embodiments, wherein, at each map coordinate(s), the concentration map specifies the substance having the highest concentration (i.e. density), the NN may be a classification NN. According to some such embodiments, the NN may be a CNN, an AlexNet, a VGG NN, a ResNet, or may include a VAE.

According to some embodiments, wherein the concentration map specifies the concentrations of the substances to within density ranges, the NN may be a classification NN.

According to some such embodiments, the NN may be a CNN, an AlexNet, a VGG NN, a ResNet, or a VAE (as described in the Depth-Profiling Methods Subsection).

According to some embodiments, wherein the concentration map specifies the density of a substance in terms of a (single) numerical value, the NN may be a regression NN.

According to some embodiments, e-beam source 602 may be laterally and/or vertically translatable. According to some embodiments, e-beam source 602 may be configured to allow projecting the e-beam at any one of a plurality of incidence angles relative to sample 60. In particular, according to some such embodiments, e-beam source 602 may be configured to allow projecting the e-beam not only perpendicularly to a top surface 64 (i.e. at an incidence angle of 100°) of sample 60 but also obliquely relative thereto (e.g. at an incidence angle of about 10°, about 20°, or about 30°). In such embodiments, the ML-derived algorithm (executable by computational module 606) may depend on, or may be configured to take into account, the incidence angles of each of the e-beams in order to output the concentration map.

According to some embodiments, electron sensing module 604 (or one or more components thereof) may be laterally and/or vertically translatable, thereby allowing to control the collection angle (i.e. sense backscattered electrons returned from sample 60 at a desired return angle). According to some embodiments, backscattered electrons generated by e-beams of different landing energies may be sensed at different return angles, respectively. In such embodiments, the ML-derived algorithm (executable by computational module 606) may be configured to take into account the return angles of the e-beams in computing the concentration map.

According to some embodiments, electron sensing module 604 may include a plurality of electron sensors, which are configured to sense backscattered electrons at each of plurality of return angles (equivalently, scattering angles). For example, a first electron sensor (e.g. a first BSE detector) may be positioned so as to measure backscattered electrons returned at a scattering angle of about 180°, while a second electron sensor (e.g. a second BSE detector) may be positioned so as to measure backscattered electrons returned at a scattering angle of about 170°, about 160°, or about 150°. In such embodiments, the ML derived algorithm (executable by computational module 606) may be configured to receive as inputs the intensities of backscattered e-beams sensed (measured) by each of the electron sensors, respectively, labelled by the respective return angle.

According to some embodiments, wherein electron optics 612 includes an energy filter, as described above, the ML derived algorithm (executable by computational module 606) may be configured to receive as inputs sensed electrons data sets including measurement data obtained for different threshold energies of the energy filter. In such embodiments, in addition to being labelled by the landing energy, (at least some of) the sensed electrons data sets may further be labelled by the threshold energy.

FIG. 7 schematically depicts a SEM 720, according to some embodiments. SEM 720 corresponds to specific embodiments of SEM 620 (of system 600). SEM 720 includes an electron gun 702, a first electron sensor 704a, and a second electron sensor (or sensor assembly) 704b. Electron gun 702 corresponds to specific embodiments of electron source 602. First electron sensor 704a and second electron sensor 704b are included in, or jointly constitute, an electron sensing module, which corresponds to specific embodiments of electron sensing module 604. Second electron sensor 704b may include a hole 760 for passage therethrough of e-beams prepared by SEM 720. SEM 720 additionally includes a deflection assembly 712 (e.g. including a plurality of magnets and/or magnetic coils). Deflection assembly 712 may be included in, or constitute, electron optics (not all components thereof are shown) of SEM 720, which correspond to specific embodiments of electron optics 612. A controller of SEM 720 is not shown in FIG. 7.

SEM 720 further includes an energy filter 752. Energy filter 752 is configured to filter therethrough electrons with an energy above a selectable threshold energy. According to some embodiments, and as depicted in FIG. 7, energy filter 752 may include at least one electrically conductive grid 756 (i.e. at least one perforated metallic plate) positioned below first electron sensor 704a. Grid 756 may be maintained at a selectable (electric) potential, such that only electrons having an energy above a threshold energy may pass through grid 756 and reach first electron sensor 704a.

Also shown is a stage 724 and a sample 70, which is mounted thereon. Stage 724 and sample 70 correspond to specific embodiments of stage 624 and sample 60, respectively.

According to some embodiments, and as depicted in FIG. 7, in operation, an e-beam 701, generated by electron gun 702, impinges normally on sample 70. E-beam 701 is laterally offset (i.e. laterally displaced) by deflection assembly 712, thereby preparing an incident e-beam 705. Returned e-beams 715 are produced as a result of the striking of e-beam 705 on sample 70, and, in particular, the penetration thereof thereinto. Returned e-beams 715 include an e-beam 715a and e-beams 715b. E-beam 715a propagates oppositely to e-beam 705 (i.e. e-beam 715a is scattered at 180°). E-beams 715b are returned at scattering angles different from 180° and are sensed by second electron sensor 704b.

E-beam 715a passes through deflection assembly 712 and is laterally offset thereby, following which, a portion 725a of e-beam 715a is filtered through energy filter 752 and is sensed by first electron sensor 704a. By changing the potential at which grid 756 is maintained, the minimum energy of electrons in portion 725a is accordingly changed.

SEM 720 is thus seen to be configured to obtain sensed electrons data sets corresponding to a plurality of scattering angles and which may be “parsed” by the energy of the electrons in the returned e-beams.

According to some embodiments, the electron optics may further include a compound lens 762 configured to focus e-beam 705 on sample 70. To this end, compound lens 762 may include a magnetic lens and an electrostatic lens (not shown). According to some embodiments, second electron sensor 704b may be disposed between compound lens 762 and sample 70.

### Training Methods

According to an aspect of some embodiments, there is provided a method 800 for training a NN for use in non-destructive BSE based depth-profiling of samples: The NN is configured to (i) receive as inputs, sensed electrons data sets of a sample, obtained by projecting on the sample (one at a time) e-beams at a plurality of landing energies, respectively, and (ii) output a concentration map of the sample. Method 800 may thus be employed to train a NN to perform operation 120 of method 100 or operation 320 of method 300. Accordingly, the NN may be any one of the NNs described above in relation to methods 100 and 300. Method 800 includes:
An operation 810, wherein training data for the NN are generated by performing:
   A suboperation 810a of generating calibration data by performing for each of a plurality of Nₛ samples:
      A suboperation 810a1 of projecting on the sample a plurality of e-beams at a first plurality of landing energies, respectively, and sensing (e.g. using an electron sensor to detect) at least backscattered electrons returned from the sample.
      A suboperation 810a2 of obtaining a measured concentration map, which characterizes at least a vertical dimension of the sample.
   A suboperation 810b, wherein simulated training data sets for the NN are generated by performing:
      A suboperation 810b1 of using the calibration data to calibrate a computer simulation, which is configured to receive as inputs a concentration map of a sample, and a landing energy of an e-beam projected on the sample, and output corresponding a simulated electrons data set.
      A suboperation 810b2 of using the calibrated computer simulation to generate simulated electrons data sets corresponding to additional landing energies and/or additional samples.
An operation 820, wherein the NN is trained using (i) as inputs, at least the simulated electrons data sets, each labelled by the respective landing energy, and (ii) as outputs, concentration maps, corresponding to the simulated electrons data sets, respectively.

The sensed electrons data sets, together with the corresponding measured concentration maps of the Nₛ samples, constitute “ground truth” (GT) data, which is used to calibrate the simulation, as further elaborated in detail below.

In suboperation 810a, the Nₛ samples may be of the same design intent, and, in particular, of the same design intent as the samples which the NN is trained to depth-profile. According to some embodiments, wherein the NN is to be trained depth-profile samples of other design intents (e.g. slightly different design intents), operation 810 may be repeated with respect to each of additional pluralities of samples (per each of the other design intents).

In suboperation 810b1, the computer simulation may be calibrated such that, for each of the measured concentration maps and landing energies, the simulated electrons data set, output by the computer simulation, agrees to within a required precision with the respective sensed electrons data set.

According to some embodiments, wherein each of a plurality of substances, which is included in the sample, is to be profiled, in each of the Nₛ implementations of suboperation 810a2, the measured concentration maps specify, potentially after processing of raw measurement data, the respective substance having the highest density about each map coordinate(s). Alternatively, according to some embodiments, the measured concentration maps, specify, potentially after processing of raw measurement data, the densities of substances about each map coordinate(s) to within respective density ranges.

According to some embodiments, the NN may be a classification NN whose outputs specify, for each map coordinate(s), the substance having the highest density thereabout. According to some such embodiments, the NN may be a CNN, an AlexNet, a VGG NN, a ResNet, or may include a VAE.

According to some embodiments, the NN may be a classification NN whose outputs specify, for each map coordinate(s), the densities of substances thereabout to within respective density ranges. According to some such embodiments, the NN may be a CNN, an AlexNet. a VGG NN, a ResNet, or may include a VAE.

According to some embodiments, the NN may be a regression NN whose outputs specify, for each map coordinate(s), the densities of substances thereabout in terms of respective (single) numerical values.

Suboperation 810a1 may be implemented as specified in the description of measurement operation 110 of method 100, and suboperation 310 of method 300, in the Depth-Profiling Methods Subsection above.

Suboperation 810a2 may be implemented by profiling lamellas extracted from the sample and/or slices shaved off the sample. According to some embodiments, the profiling may be performed using a SEM or a transmission electron microscope.

According to some embodiments, (i) the output of the NN is a three-dimensional concentration map, (ii) in each of the Nₛ implementations of suboperation 810a2 the measured concentration map is three-dimensional, (iii) in each of the Nₛ implementations of suboperation 810a1 the e-beams are projected on each of the samples at each of a plurality of lateral locations thereon, and (iv) in suboperation 810b2 the simulated electrons data sets are generated per each of the plurality of lateral locations. According to some such embodiments, in operation 820 the simulated electrons data sets, used as inputs in training the NN, are further labelled by the lateral locations, respectively, at which the inducing e-beam impinged.

According to some embodiments, initially, i.e. prior to the calibration of the computer simulation in suboperation 810b1, the computer simulation specifies a set of initial point spread functions

$$( PSFs ) {\{ {H}_{E}^{( i )} \}}_{E} = \{ {H}_{{E}_{1}}^{( i )} , {H}_{{E}_{2}}^{( i )} , … , {H}_{{E}_{{N}_{E}}}^{( i )} \} ,$$

wherein N_{E} is the number of landing energies.

Each of the H_{E}⁽ⁱ⁾ corresponds to a respective landing energy (as indicated by the subscript E) from a set of landing energies, which includes the first plurality of landing energies, and, optionally, other landing energies. For each landing energy, the corresponding initial PSF specifies, as a function of the depth within the sample (and lateral coordinates in the three-dimensional case), the intensity of e-beams, per particle or unit mass, which are scattered (e.g. elastically backscattered) towards an electron sensor. The set of initial PSFs may be obtained by a (second) computer simulation, which models the striking and penetration of an e-beam into a sample—which has the same design intent as the Nₛ samples—and the elastic interactions of electrons in the e-beam with matter in the sample. In suboperation 810b1, each of the initial PSFs is calibrated, thereby obtaining a set of calibrated PSFs {H_{E}^{(c)}}_{E}. The superscripts i (for “initial”) and c (for “calibrated”) serve to distinguish between the two sets. The {H_{E}^{(c)}}_{E} are used to generate the simulated electrons data sets. In particular, according to some embodiments, the {H_{E}^{(c)}}_{E} may be used to obtain from “simulated” concentration maps the simulated electrons data sets. The simulated concentration maps may constitute slight variations on each of the Nₛ measured concentration maps obtained in the Nₛ implementations of suboperation 810a2. According to some embodiments, a ratio of a number of the simulated electrons data sets to a number of the sensed electrons data sets may be between about 100 and about 1,000.

It is noted that in the one-dimensional case (i.e. when a one-dimensional concentration map of the sample is to be obtained), each of the (initial and calibrated) PSFs is a single-variable function, which depends only on the depth, and accordingly, in suboperation 810b2: {H_{E}⁽ⁱ⁾(z)}_{E}→{H_{E}^{(c)}(z)}_{E}, wherein the coordinate z (i.e. the vertical coordinate) parameterizes the depth. In the three-dimensional case (i.e. when a three-dimensional concentration map of the sample is to be obtained), each of the PSFs is a three-variable function (i.e. of the lateral coordinates x and y, and the vertical coordinate z), and is moreover indexed by the coordinates L=(Lₓ, L_{y}) of the lateral location at which the respective e-beam impinges on the sample. Accordingly, in such embodiments, in suboperation 810b2: {H_{E,L}⁽ⁱ⁾(x, y, z)}_{E,L}→{H_{E,L}^{(c)}(x, y, z)}_{E,L}.

More specifically, as a non-limiting example, assuming that the measured e-beam intensity I_{E} is Gaussian-distributed (alternatively, other distributions may be assumed, such as a Poisson distribution), the probability of measuring the intensity I_{E} (or, more precisely, intensities within a small intensity interval centered about I_{E}), given the actual (true) H_{E}, is p(I_{E}|H_{E}, ρ)∝exp [−N(I_{E}−∫dz′H_{E} (z′)ρ(z−z′))²]. Here the ρ denotes a density (e.g. particle density) of the profiled substance (measured in suboperation 810b2) and Nis a normalization factor. The above equation applies both to the one-dimensional case and the three-dimensional case. In the latter case, the presence of the subscript L has been left implicit.

In principle, the H_{E}(z) should maximize the likelihoods p(I_{E,s}|H_{E}(z), ρₛ(z)). The added subscript s denotes the sample (from the Nₛ samples of suboperation 710a). The I_{E, s} are the intensities, measured in the Nₛ implementations of suboperation 810a1, and the ρₛ are densities of the profiled substance in each of the Nₛ samples, respectively. Equivalently, discretizing the H_{E}(z), such that each H_{E} (z) is approximated by a N_{z} component (row) vector H_{E}, which specifies averaged values of H_{E} about each of N_{z} depths (which may or may not be equally spaced), the H_{E}^{(c)}(z) (or, more precisely, the discretization thereof. H_{c}) may obtained by solving the optimization problem: H_{c}=argmin_{H} (∥Hρ−I∥_{F}²+λ∥H−Hᵢ∥_{F}²). Here H is a N_{E}×N_{z} matrix, wherein N_{E} is the number of landing energies. That is, the rows of H are constituted by the H_{E}. ρ is a N_{z}×Nₛ matrix. For each 1≤j≤Nₛ, the j-th column of ρ specifies averaged values of the density of the profiled substance—in the j-th sample—about each of the N_{z} depths. According to some embodiments, N_{E} is at least as large N_{z}. I is a N_{E}×Nₛ matrix. For each 1≤j≤Nₛ, the j-th column of I specifies the intensity of the scattered e-beam, per each of the plurality of landing energies, measured in suboperation 810a1 when applied (i.e. performed) with respect to the j-th sample. The rows of Hᵢ are constituted by the (row) vectors H_{E}⁽ⁱ⁾, which are obtained by discretizing the H_{E}⁽ⁱ⁾ (z). The subscript F indicates the Frobenius norm. λ is a hyperparameter whose value may be “manually” adjusted to improve the estimate of H. Similarly, the degree of discretization (i.e. the number of N_{z}) may be selected based on the required accuracy. The optimization problem may be solved iteratively, e.g. using a modified Richardson-Lucy algorithm, wherein, as a first approximation, H is taken to equal Hᵢ.

If more than one substance is to be profiled, for example, (i) when the NN (to be trained) is to output a concentration map specifying about each map coordinate(s) the substance having the highest concentration, or (ii) when the NN (to be trained) is to output a concentration map specifying about each map coordinate(s) the densities of a two or more substances included in a sample (e.g. to within respective density ranges), then the above optimization procedure is carried out with respect to each of the profiled substances.

It is noted that the above optimization problem is underdetermined, and so has no unique solution. There is thus no absolute guarantee that the deduced H_{E}^{(c)} will closely match the actual H_{E}. Nevertheless, if the initially simulated PSFs, i.e. the H_{E}⁽ⁱ⁾, are close to the actual H_{E}, the solution of the optimization problem will likely converge to closely matching functions.

In the three-dimensional case, each of the H_{E,L} (x, y, z) (L specifies the lateral location on the sample on which the respective e-beam is incident) may be approximated by a Nᵣ component (row) vector H_{E, L}, which specifies averaged values of H_{E, L} about each of Nᵣ locations (specified by the vector r=(x, y, z)) in the sample. The rows of H are constituted by the H_{E, L}. ρ is now a Nᵣ×Nₛ matrix, so that Hρ is a (N_{E}·N_{L})×Nₛ matrix, wherein N_{L} is the number of impinged lateral locations on the sample. I is a (N_{E}·N_{L})×Nₛ matrix. For each 1≤j≤Nₛ, the j-th column of I specifies the intensity of the sensed e-beams—per each of the N_{L} impinged locations and each of the plurality of landing energies—measured in suboperation 810a1 when applied (i.e. performed) with respect to the j-th sample. According to some embodiments, N_{E} equals at least N_{z}.

According to some embodiments, in suboperation 810b2, some of the additional samples may be of different design intent than the plurality of samples of suboperation 810a.

According to some embodiments, suboperation 810b and operation 820 may reapplied when relevant new calibration data becomes available. More specifically, even after the NN has been trained (and can be used to implement data analysis operation 120 of method 100), as new calibration data—particularly, pertaining to other design intent (e.g. new internal geometries and/or concentrations of constituents, and, optionally, even other constituents)—becomes available, suboperation 810b and operation 820 may be reapplied to expand the applicability of method 100 and/or improve the accuracy thereof.

According to some embodiments, wherein, in suboperation 810b2, the simulated electrons data sets are generated for, or also for, additional samples, in operation 820, each of the additional simulated electrons data sets, used as inputs in training the NN, is further labelled by the additional sample with respect to which the additional simulated electrons data were obtained.

According to some embodiments, operation 820 includes an initial training suboperation, which may be unsupervised, in which latent variables, which characterize the simulated electrons data sets, are extracted.

According to some alternative embodiments, Hᵢ may be calibrated employing a U-Net deep learning NN. That is, H_{c}=U_{F}(θ)∘Hᵢ, wherein U_{F}(θ)—the U-Net—is a CNN and the symbol ∘ denotes the application of U_{F}(θ) on Hᵢ. The components of the vector θ represent adjustable parameters of the U-Net. U_{F}(θ) is obtained from the GT data constraints, which can be compactly expressed as I=(U_{F}(θ)∘Hᵢ) ρ.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. No feature described in the context of an embodiment is to be considered an essential feature of that embodiment, unless explicitly specified as such.

Although operations of methods, according to some embodiments, may be described in a specific sequence, the methods of the disclosure may include some or all of the described operations carried out in a different order. In particular, it is to be understood that the order of operations and suboperations of any of the described methods may be reordered unless the context clearly dictates otherwise, for example, when a latter operation requires as input the output of earlier operation or when a latter operation requires the product of an earlier operation. A method of the disclosure may include a few of the operations described or all of the operations described. No particular operation in a disclosed method is to be considered an essential operation of that method, unless explicitly specified as such.

Although the disclosure is described in conjunction with specific embodiments thereof, it is evident that numerous alternatives, modifications, and variations that are apparent to those skilled in the art may exist. Accordingly, the disclosure embraces all such alternatives, modifications, and variations that fall within the scope of the appended claims. It is to be understood that the disclosure is not necessarily limited in its application to the details of construction and the arrangement of the components and/or methods set forth herein. Other embodiments may be practiced, and an embodiment may be carried out in various ways.

The phraseology and terminology employed herein are for descriptive purpose and should not be regarded as limiting. Citation or identification of any reference in this application shall not be construed as an admission that such reference is available as prior art to the disclosure. Section headings are used herein to ease understanding of the specification and should not be construed as necessarily limiting.

What is claimed is:

1. A system for non-destructive depth-profiling of samples, the system comprising:
an electron beam (e-beam) source configured to project e-beams on a sample at each of a plurality of landing energies;
an electron sensing module configured to sense electrons returned from the sample, thereby obtaining a respective sensed electrons data set, wherein the sensed electrons comprise at least backscattered electrons; and
a computational module configured to generate, based on the sensed electrons data sets, a concentration map characterizing at least a vertical dimension of the sample.

2. The system of claim 1, further configured to allow projecting the e-beams on each of controllably selectable lateral locations on the sample; and
wherein the computational module is configured to, in generating the concentration map, take into account sensed electrons data sets, obtained by the electron sensing module for each of the lateral locations; and
wherein the concentration map is three-dimensional.

3. The system of claim 1, wherein the electron sensing module comprises two or more electron sensors configured to sense electrons returned at each of two or more return angles, respectively.

4. The system of claim 1, wherein, the computational module is configured to, in generating the concentration map, take into account a design intent of the sample.

5. The system of claim 1, wherein the sample is a semiconductor specimen.

6. The system of claim 4, wherein the computational module is configured to execute a machine learning (ML) derived algorithm, whose output is the concentration map and whose inputs comprise the sensed electrons data sets, each labelled at least by the respective landing energy.

7. The system of claim 6, wherein the ML derived algorithm is or comprises a classification neural network (NN); and
wherein at each map coordinate(s) the concentration map specifies (i) a substance, having a highest density about the map coordinate, out of a plurality of substances, which the sample comprises, and/or (ii) densities of one or more substances, which the sample comprises, to within density ranges from a plurality of density ranges.

8. A computer-based method for non-destructive depth-profiling of samples, the method comprising:
a measurement operation comprising for each of a plurality of landing energies, selected so as to allow probing the sample at a plurality of depths:
projecting an electron beam (e-beam) on a sample, which penetrates the sample to a respective depth determined by the landing energy; and
sensing electrons returned from the sample, thereby obtaining a respective sensed electrons data set, wherein the sensed electrons comprise backscattered electrons; and
a data analysis operation, wherein a concentration map, characterizing at least a vertical dimension of the sample, is generated from the sensed electrons data sets.

9. The method of claim 8, wherein the measurement operation is performed with respect to each of a plurality of lateral locations on the sample on which the respective plurality of e-beams is projected; and
wherein, in the data analysis operation, sensed electrons data sets obtained by projecting the e-beams on each of the lateral locations, are taken into account in generating the concentration map, which is three-dimensional.

10. The method of claim 8, wherein the sample is a semiconductor specimen.

11. The method of claim 8, wherein, in the data analysis operation, a design intent of the sample is taken into account; and
wherein, in the data analysis operation, the concentration map is obtained as an output of a machine learning (ML) derived algorithm, whose inputs comprise the sensed electrons data sets, obtained for each of the landing energies and labelled thereby.

12. The method of claim 11, wherein the ML derived algorithm is a classification neural network (NN); and
wherein at each map coordinate(s) the concentration map specifies (i) a substance, having a highest density about the map coordinate(s), out of a plurality of substances, which the sample comprises, and/or (ii) densities of one or more substances, which the sample comprises, to within density ranges from a plurality of density ranges.

13. A method for training a neural network (NN) for non-destructive depth-profiling of samples, the method comprising operations of:
generating training data for a NN, which is configured to receive as inputs, sensed electrons data sets of a sample, obtained for each of a plurality of landing energies of inducing electron beams (e-beams), and to output a concentration map of the sample, by sub-operations of:
generating calibration data by, for each of a plurality of samples:
projecting thereon a plurality of e-beams at a first plurality of landing energies, respectively, and sensing at least backscattered electrons returned from the sample; and
obtaining a measured concentration map, which characterizes at least a vertical dimension of the sample;
generating simulated training data for the NN by:
using the calibration data to calibrate a computer simulation, which is configured to receive as inputs a concentration map of a sample, and a landing energy of an e-beam projected on the sample, and output a corresponding simulated electrons data set; and
using the calibrated computer simulation to generate simulated electrons data sets corresponding to additional landing energies and/or additional samples; and
training the NN using (i) at least the simulated electrons data sets, each labelled by the respective landing energy, as inputs, and (ii) concentration maps, corresponding to the simulated electrons data sets, respectively, as outputs.

14. The method of claim 13, wherein the computer simulation is calibrated such that for each pair of measured concentration map, obtained in the suboperation of generating the calibration data, and landing energy, which is input into the computer simulation, a simulated electrons data set, output by thereby, agrees to within a required precision with the respective sensed electrons data set.

15. The method of claim 13, wherein the sensed electrons data sets, used as inputs for the NN, comprise sensed electrons data sets obtained for each of a plurality of lateral locations on which the inducing e-beams respectively impinge on the sample; and
wherein, in the generating of the calibration data, the pluralities of e-beams are projected at pluralities of lateral locations on the samples, respectively, and the measured concentration maps are three-dimensional.

16. The method of claim 13, wherein, prior to the calibration thereof, the computer simulation specifies initial point spread functions (PSFs) at least for each of the first plurality of landing energies;
wherein, in the calibration, the initial PSFs are calibrated, thereby obtaining calibrated PSFs; and
wherein the calibrated PSFs are obtained by about maximizing a likelihood for obtaining the sensed electrons data sets, given the measured concentration maps and starting from the initial PSFs.

17. The method of claim 16, wherein a modified Richardson-Lucy algorithm is used to obtain the calibrated PSFs.

18. The method of claim 13, wherein the measured concentration maps are obtained by profiling lamellas extracted from each of the plurality samples and/or slices shaved thereof; and
wherein the profiling of lamellas is performed using transmission electron microscopy and/or a scanning electron microscopy.

19. The method of claim 13, wherein each of the plurality of samples comprises a semiconductor specimen.

20. The method of claim 13, wherein the NN is a classification NN, and wherein at each map coordinate(s) the concentration map, output by the NN, specifies: (i) a substance, having a highest density about the map coordinate(s), out of a plurality of substances that the respective sample comprises, and/or (ii) densities of the one or more substances, which the sample comprises to within one of a plurality of density ranges.
